(19) United States
(12) Patent Application Publication
(10) Pub. No.: US 2003/0099907 A1
(43) Pub. Date: May 29, 2003

(54) Process of rectifying a wafer thickness

(76) Inventors: Ming-Ta Tei, Hsinchu (TW); Chuen-Jye Lin, Taichung Hsien (TW); Hei-Mei Chen, Hsinchu (TW)

Correspondence Address: J.C. Patents, Inc., 4 Venture, Suite 250, Irvine, CA, 92618, US

(21) Appl. No.: 09/997,941

(22) Filed: Nov. 29, 2001

(51) Int. Cl. G03F 7/00

(52) U.S. Cl. 430/313; 430/394; 430/314

(57) ABSTRACT

A process of rectifying a wafer thickness includes the following steps. A wafer is first provided with an active side. Next, a lithography process is performed to form a photoresist at the active side and to pattern at least a opening therein. Subsequently, a welding material is formed in the openings. Afterward, an adhesive carrier is attached over the patterned photoresist. Next, rectification operation is performed to reduce the wafer thickness. Subsequently, the adhesive carrier is removed and then the patterned photoresist is removed.

### BACKGROUND OF THE INVENTION

1. Field of the Invention

The invention relates in general to a process of rectifying a wafer thickness. More particularly, the invention relates to a process for rectifying a wafer thickness that does not generate adhesive residues.

2. Description of the Related Art

Nowadays, electronic equipment are increasingly used to achieve many various tasks. With the development of electronics technology, miniaturization, multi-function task, and comfort of utilization are among the principle guidelines of electronic product manufacturers. More particularly in semiconductor manufacture process, after the chips with their electronic component devices are achieved on the active surface of a wafer, a rectification operation is typically performed to substantially reduce the wafer thickness.

FIGS. 1-5 are various cross-sectional views showing a conventional process of rectifying a wafer thickness. In FIG. 1, a wafer 110 has an active surface 112 and a corresponding back surface 114. On the active surface 112 of the wafer 110, a passivation layer 116 typically has a plurality of openings that expose a plurality of bonding pads 118 formed on the active surface 112. Through the bonding pads 118, electrical connections may be subsequently established between the chips and circuit substrates in order to fabricate semiconductor packages (not shown). An under-bump metallic (UBM) layer 120 is formed over the active surface 112 of the wafer 110 by, for example, sputtering and electroplating. The UBM layer 120 covers the bonding pads 118 and the passivation layer 116. A patterned photoresist 130 is formed on the UBM layer 120 with openings 132 therein that expose the UBM layer 120 locally over the bonding pads 118. A welding material 140a then is formed in the openings 132 by, for example, electroplating.

As shown in FIG. 2, the patterned photoresist 130 is subsequently removed by, for example, stripping. The UBM layer 120 is also partially removed by etching using the welding material 140a as etching masks.

Next referring to FIG. 3, the welding material 140a is typically reflowed to form substantially spherical lumps 140b. As described so far, bumps 146 are completed, wherein the bumps 146 are composed of the spherical lumps 140b and the UBM layer 120.

Next referring to FIG. 4, an adhesive carrier 150 is attached onto the active surface 112. The adhesive carrier 150 includes a substrate carrier 152 and an adhesive layer 154, wherein the adhesive layer 154 adheres onto the substrate carrier 152 and the active surface 112. The adhesive carrier 150 may be, for example, an adhesive tape. The adhesive layer 154 should substantially encapsulate the lumps 140b therein to ensure an optimal adhesion onto the active surface 112. The back surface 114 of the wafer 110 then is ground to reduce its thickness.

Next referring to FIG. 5, the adhesive carrier 150 then is removed, which completes the conventional grinding of a wafer.

In the above conventional process, after the adhesive carrier 150 is removed, adhesive residues typically remain on the active surface 112 and the lumps 140b. As a result, after the chips are singularized from the wafer, the adhesive residues may negatively affect subsequent bonding and electrical connections of the chips with circuit substrates (not shown). Furthermore, although spherical lumps 140b are formed to improve the adhesion of the adhesive layer 154 on the active surface 112, this adhesion may still be deficient due to an incompact arrangement that vacant spaces, as illustrated by reference numeral 156 in FIG. 4, are generated at corners between the lumps 140b and the active surface 112 of the wafer 110. In an attempt to cure this deficiency, relatively thicker and elastic adhesive layer 154 may be used, but this solution increases the manufacture cost and its result is not satisfactory. Furthermore, the adhesive carrier 150 that substantially encapsulates the lumps 140b may be difficult to remove after grinding.

### SUMMARY OF THE INVENTION

Accordingly, an objective of the present invention is to provide a process of rectifying a wafer thickness that does not leave adhesive residues on the active surface of the wafer.

Another objective of the present invention is to provide a process of rectifying a wafer thickness in which an adhesive carrier can be easily arranged on and removed from over the active surface of the wafer for protecting the wafer active surface during the rectification operation.

To achieve the foregoing and other objectives, the present invention provides a process of rectifying a wafer thickness that comprises the following steps. A wafer is first provided with an active side. Next, a lithography process is performed to form a photoresist at the active side and to pattern at least a opening therein. Subsequently, a welding material is formed in the openings. Afterward, an adhesive carrier is attached over the patterned photoresist. Next, rectification operation is performed to reduce the wafer thickness. Subsequently, the adhesive carrier is removed and then the patterned photoresist is removed.

With respect to subsequent processes, the welding material then may be reflowed to form a plurality of substantially spherical lumps. In addition, the adhesive carrier can be an adhesive tape. Moreover, the welding material can be formed in the opening of the photoresist by a electroplating process, wherein the welding material is made of tin-lead, gold or no-lead metal. However, the welding material also can be formed in the opening of the photoresist by a printing process, wherein the welding material is made of solder paste.

Both the foregoing general description and the following detailed description are exemplary and explanatory only and are not restrictive of the invention, as claimed. It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. A simple description of the drawings is as follows.

FIGS. 1-5 are various cross-sectional views showing a conventional process of rectifying a wafer thickness; and

FIGS. 6-11 are various cross-sectional views showing a process of rectifying a wafer thickness according to an embodiment of the present invention.

FIGS. 12-21 are various cross-sectional views schematically showing a process of rectifying a wafer thickness according to another embodiment of the present invention.

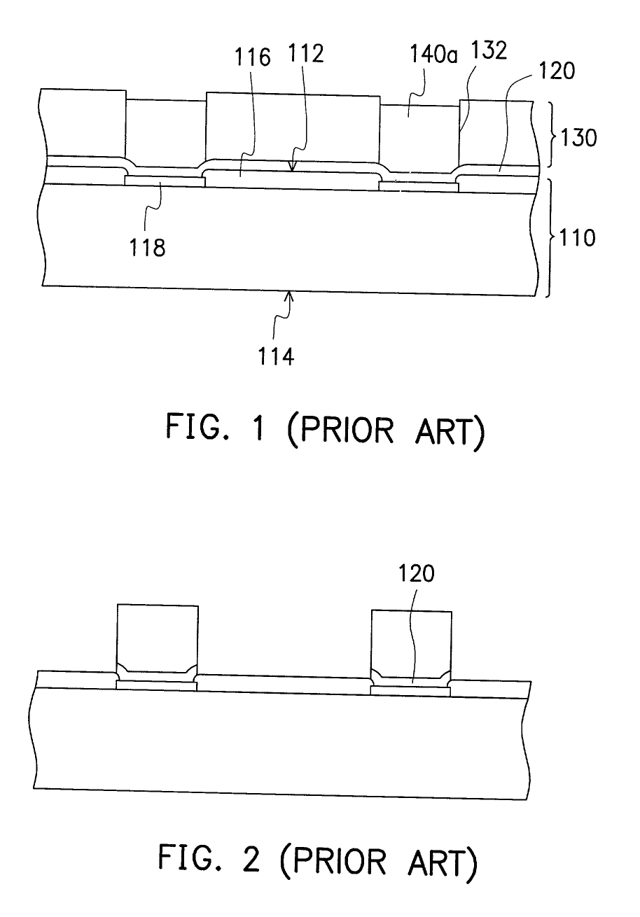

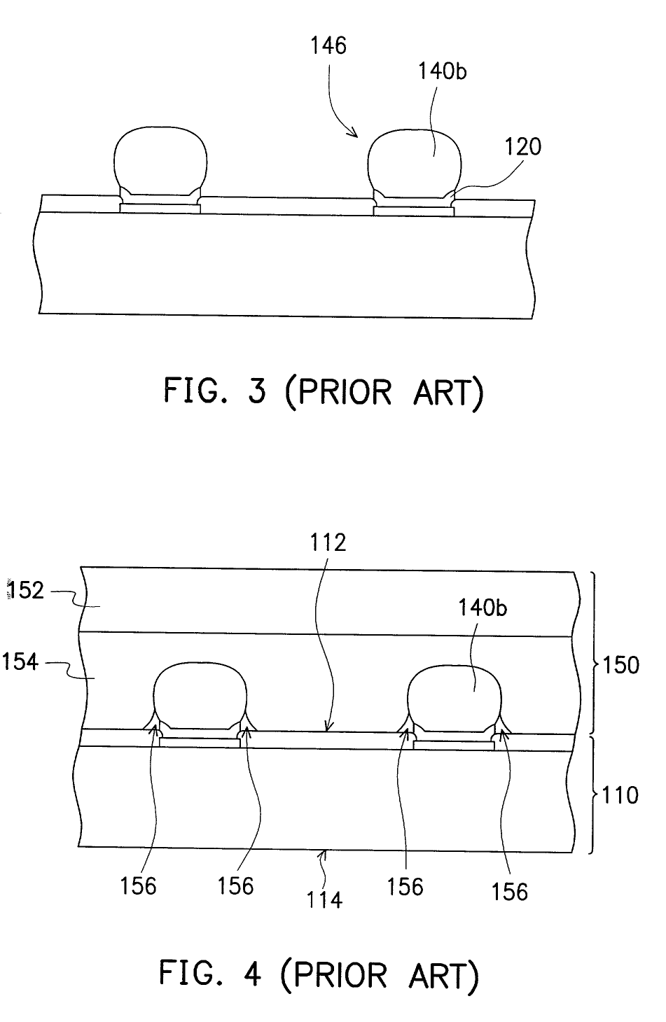

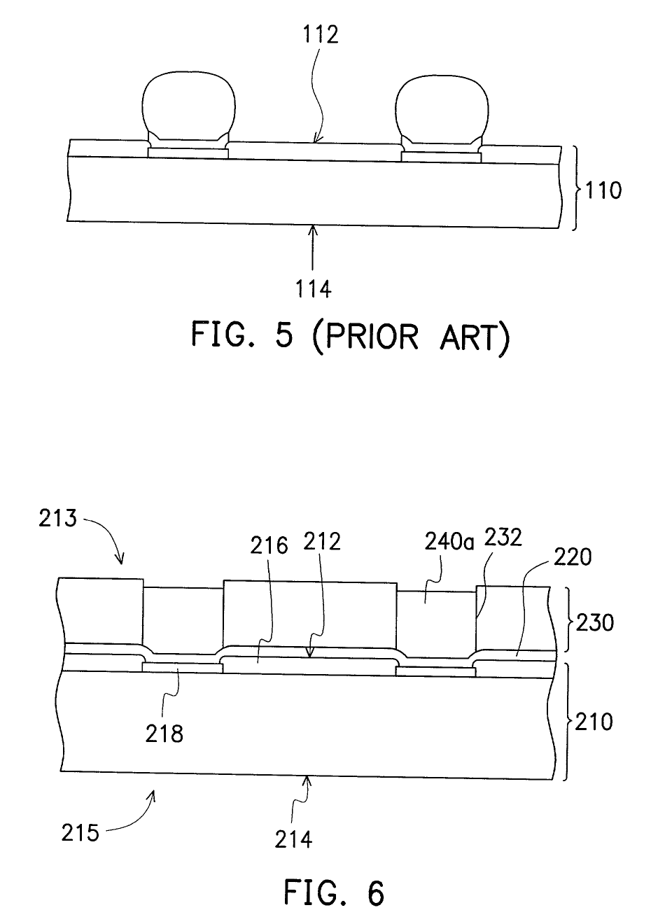

### DESCRIPTION OF THE PREFERRED EMBODIMENTS

Wherever possible, the like reference numerals will indicate the like elements and parts in the description unless otherwise illustrated. FIGS. 6-10 are various cross-sectional views schematically showing a process of rectifying a wafer thickness according to an embodiment of the present invention. Referring to FIG. 6, a wafer 210 is first provided. Various chips may be formed on the wafer 210 which has an active surface 212 and a corresponding back surface 214. The wafer 210 comprises a passivation layer 216 and bonding pads 218 formed on the active surface 212, wherein the passivation layer 216 has openings that respectively expose the bonding pads 218. In addition, the wafer 210 is defined with a active side 213 and a corresponding back side 215, wherein semiconductor units (not shown) and bonding pads 218 are formed at the active side 213. An under-bump metallic (UBM) layer 220 is formed on the active surface 212 of the wafer 210 (i.e. at the active side 213 of the wafer 210) by, for example, sputtering and subsequent electroplating. The UBM layer 220 typically consists of a multi-layer metallic structure. The UBM layer 220 covers the bonding pads 218 and the passivation layer 216, wherein the UBM layer 220 includes, for example, titanium wolfra (TiW), titanium (Ti), chromium (Cr), nickel (Ni) or copper (Cu), and its thickness is about thousands of angstroms. A photoresist 230 is formed on the UBM layer 220 (i.e. at the active side 213 of the wafer 210). The photoresist 230 is patterned to form openings 232 therein that expose the portions of the UBM layer 220 that are located over the bonding pads 218. The openings 232 may be typically formed by, for example, exposing the photoresist 230 through a pattern mask and then developing the photoresist 230. Subsequently, a welding material 240a is formed in the openings 232 of the patterned photoresist 230 by, for example, electroplating, and the welding material 240a contacts with the UBM layer 220. The welding material 240a are made of a conductive material such as tin-lead, gold, lead-free metal and so on. The welding material 240a may be pillar-like shaped.

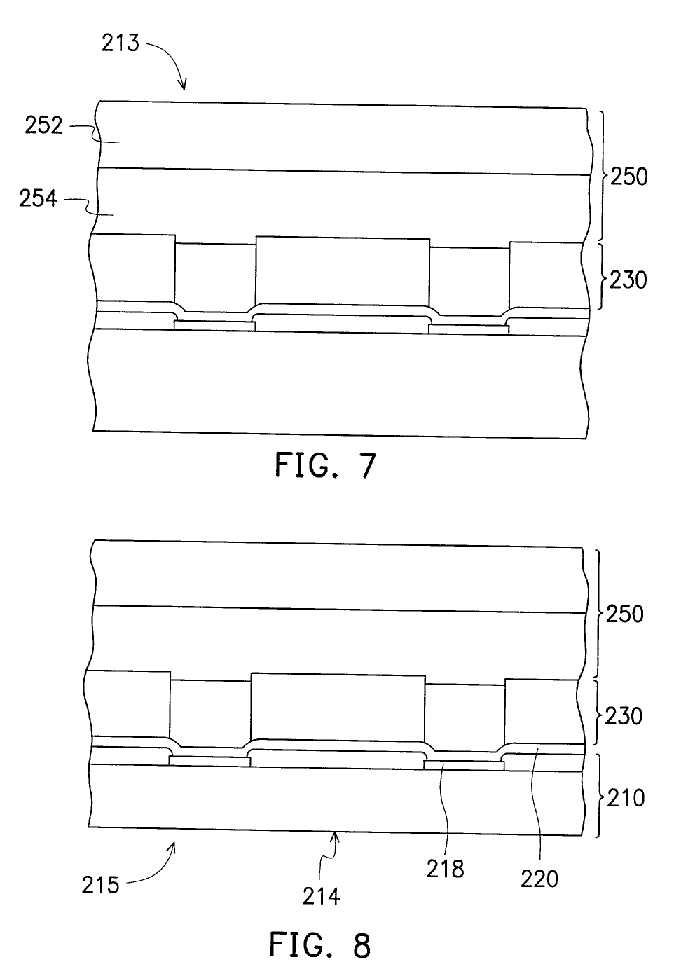

Next, referring to FIG. 7, an adhesive carrier 250, such as an adhesive tape, is disposed over the active surface 212 of the wafer 210. The adhesive carrier 250 includes a substrate carrier 252 and an adhesive layer 254 that adheres onto the substrate carrier 252. The adhesive carrier 250 is specifically attached onto the patterned photoresist 230 and the welding material 240a through the adhesive layer 254 (i.e. at the active side 213 of the wafer 210). The welding material 240a and patterned photoresist 230 provide a relatively smooth surface where the adhesive carrier 250 can easily adhere on and be removed from.

Next referring to FIG. 8, a rectification operation is performed on the wafer 210 to reduce its thickness. The rectification operation may include, for example, grinding the back surface 214 of the wafer 210 (i.e. at the back side 215 of the wafer 210). The wafer 210 may be ground according to various manners including, for example, polishing. With the adhesive carrier 250 fixedly adhering onto the photoresist 230, the active surface 212 and the welding material 240a can be thereby effectively protected while grinding. Being sufficiently rigid, the adhesive carrier 250 further may provide a support base for grinding the wafer 210. The wafer 210 can be thereby effectively ground to an optimal thickness.

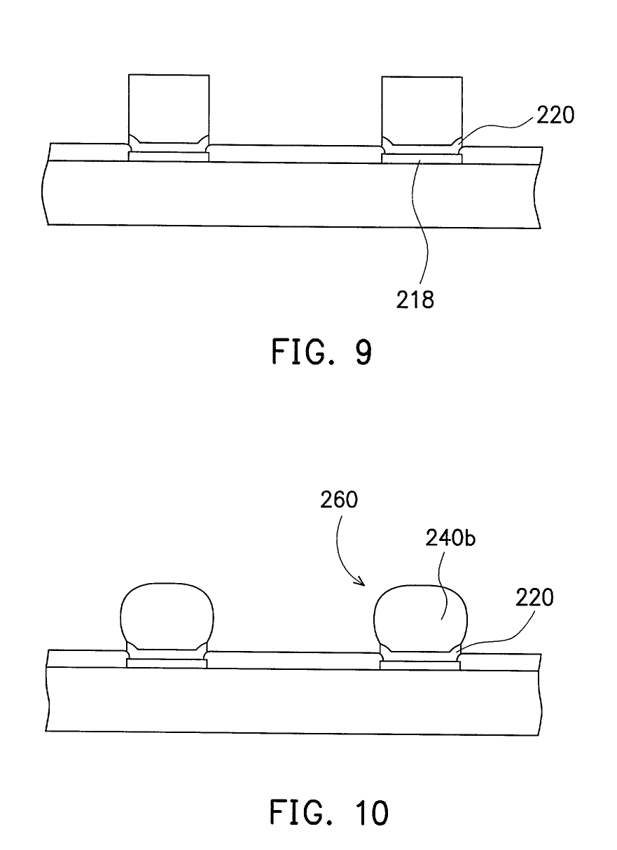

Next referring to FIG. 8 and FIG. 9, the adhesive carrier 250 and the patterned photoresist 230 are removed, thereby exposing the UBM layer 220. With the welding material 240a masking the portions of the UBM layer 220 over the bonding pads 218, the exposed parts of the UBM layer 220 then can be removed by etching, which completes the rectification process.

Referring to FIG. 10, the welding material 240a may be reflowed to form substantially spherical lumps 240b by heating processes. Bumps 246 are completed, wherein the bumps 246 are composed of the spherical lumps 240b and the UBM layer 220.

With the above process of the invention, the adhesive carrier 250 adheres onto the photoresist 230 provided with the welding material 240a therein instead of adhering to the active surface of the wafer as conventionally performed. Both adhesive carrier 250 and photoresist 230 therefore can provide a support base and provide an effective protection of the active surface 212 and the welding material 240a while grinding. Furthermore, the removal of the adhesive carrier 250 favorably does not leave any adhesive residues on the active surface 212 of the wafer 210 because the adhesive carrier 250 does not directly contact with the active surface 212. Furthermore, adhesive residues can hardly remain on the welding material 240a because the contact area between the adhesive layer 254 of the adhesive carrier 250 and the welding material 240a is substantially reduced. Therefore, after singularization, the chips of the wafer 210 can be reliably bonded to circuit substrates (not shown). In addition, the patterned photoresist 230 and the welding material 240a provide a relatively smooth surface which the adhesive carrier 250 can easily adhere on and be removed from, the adhesive layer 254 can be therefore thinner than that of the prior art and reflow process also can be reduced. As a result, the arrangement and removal of the adhesive carrier 250 over the active surface 212 of the wafer 210 is simpler, which lowers the manufacture cost.

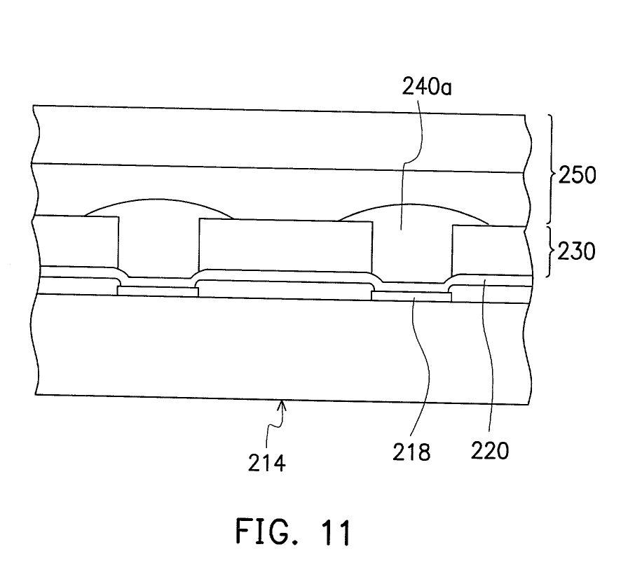

In the process of the invention, before disposing the adhesive carrier 250 over the chip surface, the welding material 240a should be formed in the openings 232 of the patterned photoresist 230. The end-stop point of filling the openings 232 with the welding material 240a may be determined according to various manners. FIG. 7 illustrates an example wherein the welding material 240a are formed in the openings 232 without extending over the openings 232 of the photoresist 230. FIG. 11 illustrates another example wherein the welding material 240a may fill the openings 232 by extending over the openings 232 of the photoresist 232 with a T-shape having rounded T-head. With the T-shaped welding material 240a, similar favorable characteristics of attaching the adhesive carrier 250 onto the patterned photoresist 230 and welding material 240a as described in the above embodiment can be obtained.

With the above process of the invention, a welding material is formed by a electroplating process. However, the application of the invention can also apply a printing process to form a welding material, as described in the following.

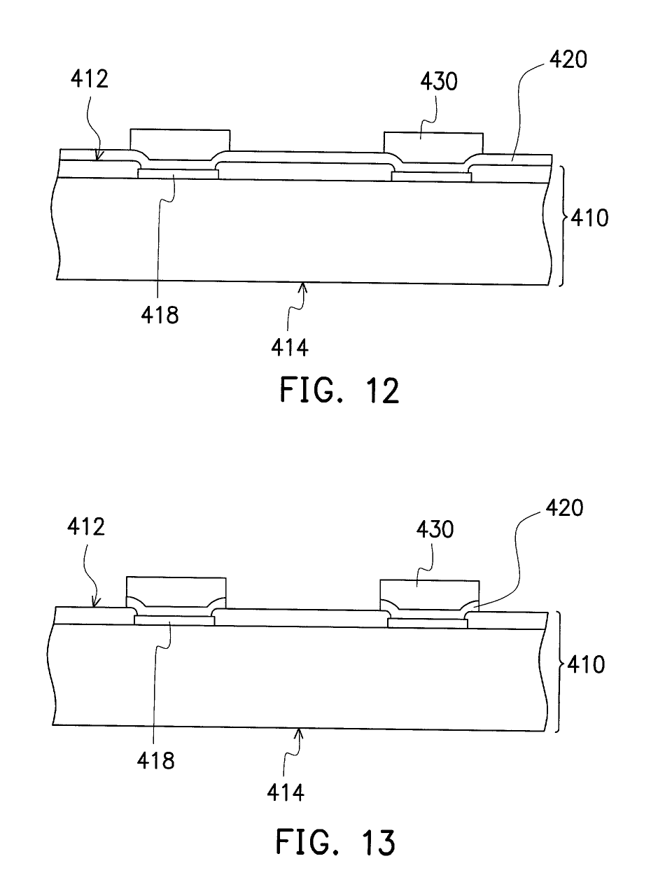

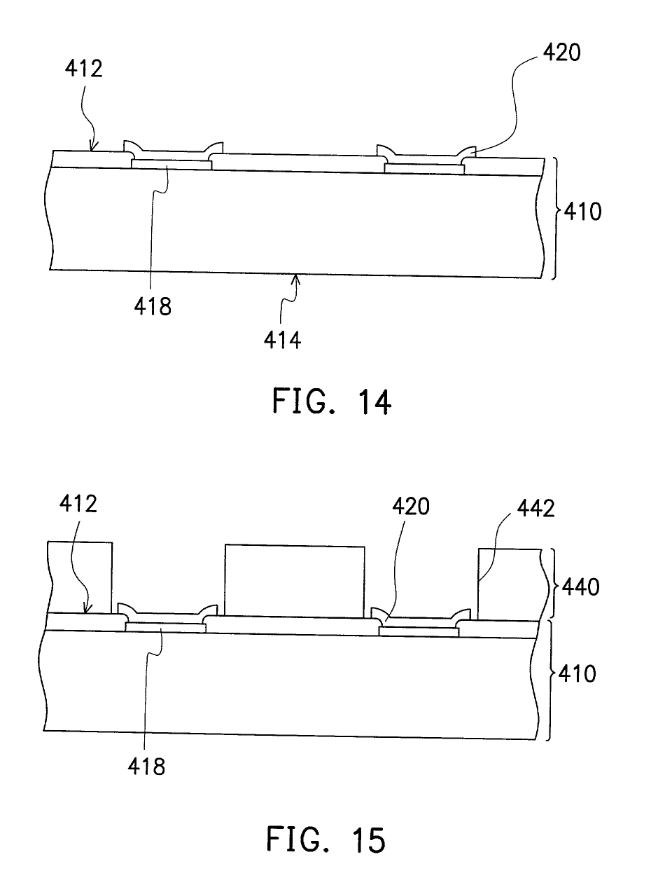

FIGS. 12-21 are various cross-sectional views schematically showing a process of rectifying a wafer thickness according to another embodiment of the present invention. Referring to FIG. 12, a wafer 410 is first provided with an active surface 412 and a corresponding back surface 414, and there are bonding pads 418 on the active surface 412 of the wafer 410. Next, an UBM layer 420 is formed on the active surface 412 of the wafer 410. Subsequently, a lithography process is performed. A photoresist is formed on the UBM layer 420 and then the photoresist is patterned to form many photoresist lumps 430 on the UBM layer 420 by an exposing process and an developing process, wherein the photoresist lumps 430 are located where bumps will be formed. The photoresist lumps 430 are formed directly over the bumps 418. Next, an etching process is performed. The UBM layer 420 exposed to the outside is removed and only left the UBM layer 420 located under the photoresist lumps 430, as illustrated in FIG. 13. Afterward, removing the photoresist lumps 430 is performed, as illustrated in FIG. 14.

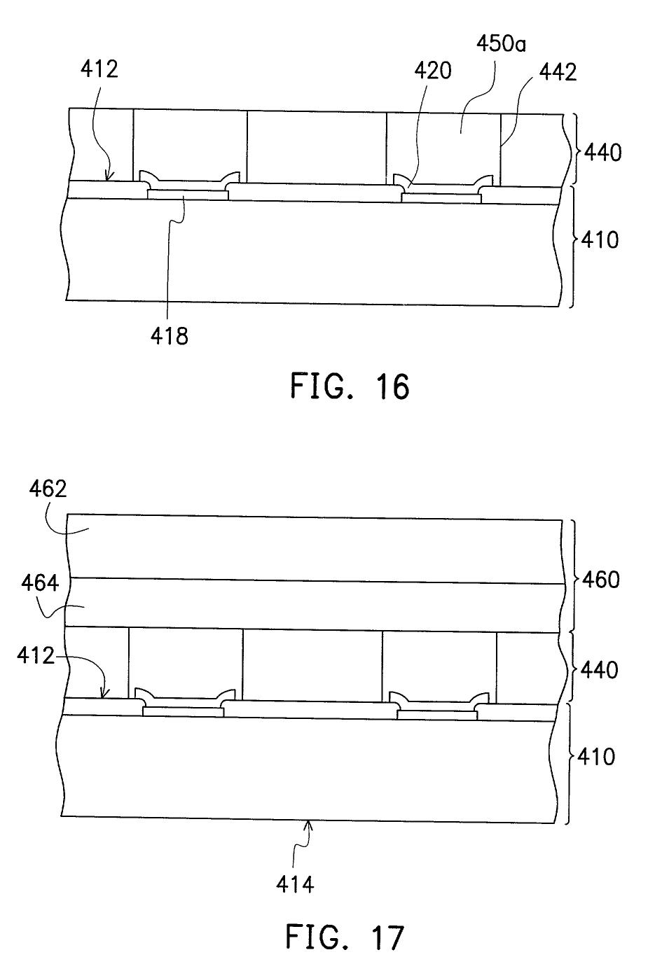

Referring to FIG. 15, a lithography process is performed. A photoresist 440 is formed on the UBM layer 420, and then the photoresist 440 is patterned to form openings 442 therein that expose the UBM layer 420 located over the bonding pads 418. The openings 442 may be typically formed by, for example, exposing the photoresist 440 through a pattern mask and then developing the photoresist 440. Subsequently, a welding material 450a is formed in the openings 442 of the patterned photoresist 440 by a printing step and the welding material 450a contacts with the UBM layer 520, as illustrated in FIG. 16. The welding material 450a are made of, for example, solder paste.

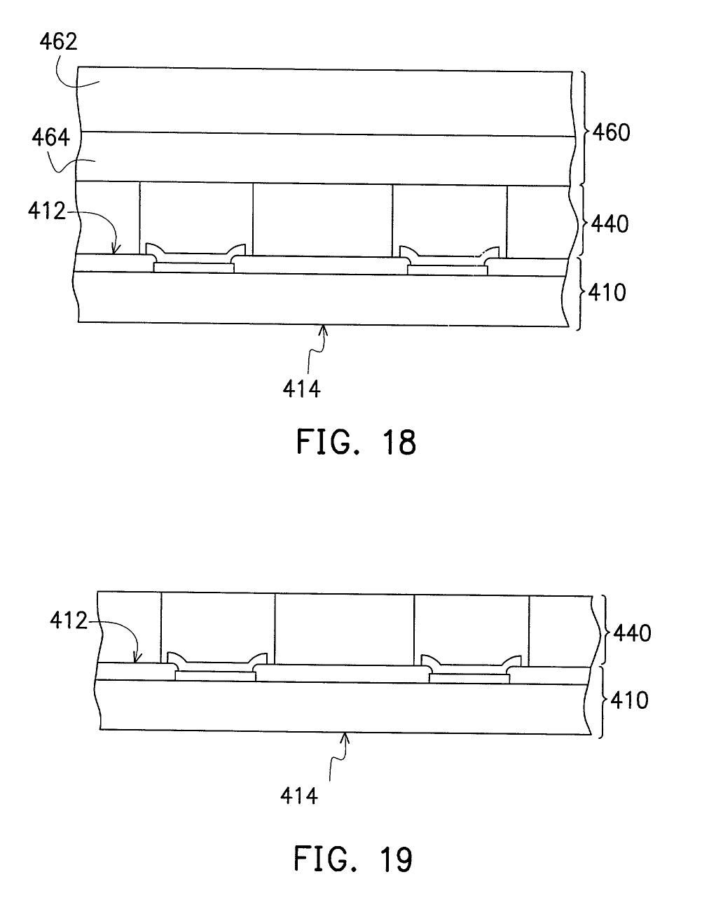

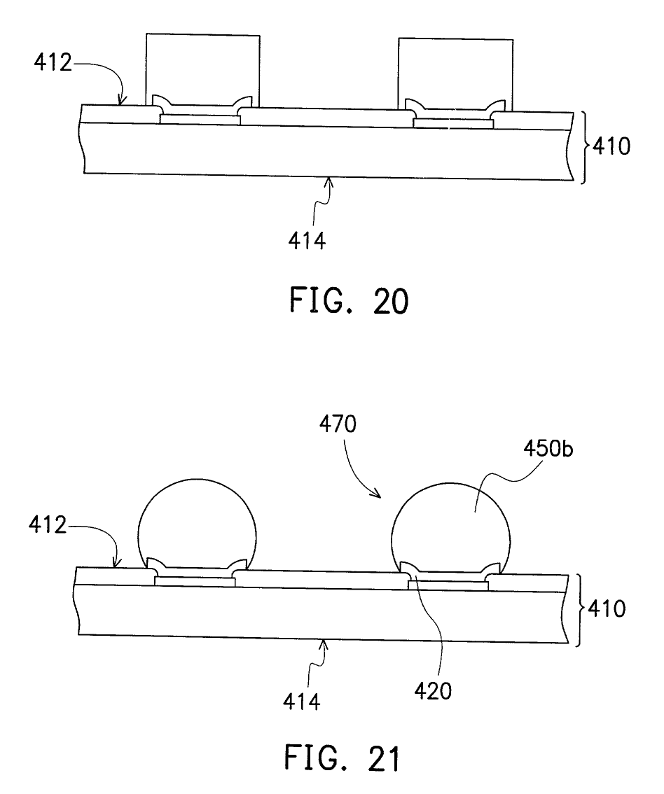

Next, referring to FIG. 17, an adhesive carrier 460, such as an adhesive tape, is disposed over the active surface 412 of the wafer 410. The adhesive carrier 460 includes a substrate carrier 462 and an adhesive layer 464 that adheres onto the substrate carrier 462. The adhesive carrier 460 is specifically attached onto the patterned photoresist 440 through the adhesive layer 254. Subsequently, a rectification operation is performed on the wafer 410 to reduce its thickness. The rectification operation may include, for example, grinding the back surface 414 of the wafer 410, as illustrated in FIG. 18. Afterward, removing the adhesive carrier 250 from the photoresist 440 is performed, as illustrated in FIG. 19. Next, removing the patterned photoresist 440 is performed, thereby exposing the active surface 412 of the wafer 410, as illustrated in FIG. 20.

Referring to FIG. 21, the welding material 450a may be reflowed to form substantially spherical lumps 450b by heating processes. Bumps 470 are completed, wherein the bumps 470 are composed of the spherical lumps 450b and the UBM layer 420.

In the above process of the invention, the UBM layer can be made of whatever metal adapted to characteristics of the UBM layer. In addition, the bonding pads can be made of aluminum or copper.

In conclusion, the process of the invention results in various advantages including not leaving adhesive residues over the active surface of the wafer after grinding. The above advantages can be obtained by grinding the back surface of the wafer while an adhesive carrier adheres on a patterned photoresist through which the welding material are formed over the active surface of the wafer. The photoresist and the welding material provide a relatively smooth surface onto which the adhesive carrier can easily and tightly adhere before grinding. Although the adhesive carrier is illustrated as particularly comprising a substrate carrier and an adhesive layer in the above description, any other types of adhesive materials that may adequately protect the active surface of the wafer during the rectification operation can be favorably used in the invention. Besides grinding, other methods known in the art for rectifying the thickness of the wafer may be used in the invention. For instance, the process of rectifying the thickness of the wafer can be performed by etching the back surface of the wafer using an etchant.

Those skilled in the art may readily make various modifications and variations of the invention with the guidelines of the above description. For example, before forming the welding material, a redistribution layer may be formed over the active surface of the wafer to redistribute the locations of the bonding pads over the active surface. The patterned photoresist and the welding material then may be formed over the redistribution layer, and the process of rectifying the wafer thickness may be subsequently performed as illustrated in the above description of the invention. The embodiments and examples that are described herein are therefore only specific ways of making and doing the invention without limiting the scope or spirit of the invention. In view of the foregoing, it is intended that the present invention cover modifications and variations of this invention provided they fall within the scope of the following claims and their equivalents.

What is claimed is:

1. A process of rectifying a wafer thickness, comprising the steps of:
providing a wafer having an active surface and a corresponding back surface;
forming an under-bump metallic (UBM) layer over the active surface of the wafer;
performing a lithogrphy process to form a photoresist on the UBM layer and then to pattern the photoresist for forming a plurality of openings therein, wherein the openings expose the UBM layer;
forming a welding material in the openings, wherein the welding material contacts with the UBM layer;
attaching an adhesive carrier over the patterned photoresist, wherein the adhesive carrier includes a substrate carrier and an adhesive layer which adheres onto the substrate carrier and the adhesive carrier is attached onto the patterned photoresist through the adhesive layer;
grinding the back surface of the wafer;
removing the adhesive carrier;
removing the patterned photoresist; and
removing the UBM layer exposed to the outside, wherein the UBM layer under the welding material is left.

2. The process according to claim 1, wherein the adhesive carrier is an adhesive tape.

3. The process according to claim 1, further comprising the step of reflowing the welding material to form a plurality of substantially spherical lumps after removing the UBM layer exposed to the outside.

4. The process according to claim 1, wherein the welding material is made of tin-lead, gold or lead-free metal.

5. The process according to claim 1, wherein the welding material fills the openings without extending over the openings of the patterned photoresist.

6. The process according to claim 1, wherein the welding material fills the openings by further extending over the openings of the patterned photoresist.

7. The process according to claim 1, wherein the welding material is formed in the openings by an electroplating process.

8. A process of rectifying a wafer thickness, comprising the steps of:
providing a wafer having an active surface and a corresponding back surface;
forming an under-bump metallic (UBM) layer over the active surface of the wafer;
performing a first lithography process to form a plurality of photoresist lumps on the UBM layer;
removing the UBM layer exposed to the outside, wherein the UBM layer under the photoresist lumps is left;
removing the photoresist lumps;
performing a second lithogrphy process to form a photoresist on the UBM layer and then to pattern the photoresist for forming a plurality of openings therein, wherein the openings expose the UBM layer;
forming a welding material in the openings, wherein the welding material contacts with the UBM layer;
attaching an adhesive carrier over the patterned photoresist, wherein the adhesive carrier includes a substrate carrier and an adhesive layer which adheres onto the substrate carrier and the adhesive carrier is attached onto the patterned photoresist through the adhesive layer;
grinding the back surface of the wafer;
removing the adhesive carrier;
removing the patterned photoresist; and
reflowing the welding material.

9. The process according to claim 8, wherein the adhesive carrier is an adhesive tape.

10. The process according to claim 8, wherein the welding material is made of solder paste.

11. The process according to claim 8, wherein the welding material is formed in the openings by a printing process.

12. A process of rectifying a wafer thickness, comprising the steps of:
providing a wafer having an active side;
performing a lithography process to form a photoresist at the active side and to pattern at least a opening therein;
forming a welding material in the openings;
attaching an adhesive carrier over the patterned photoresist;
performing a rectification operation to reduce the wafer thickness; and
removing the adhesive carrier; and
removing the patterned photoresist.

13. The process according to claim 12, wherein the adhesive carrier is an adhesive tape.

14. The process according to claim 12, further comprising the step of reflowing the welding material to form a plurality of substantially spherical lumps after removing the patterned photoresist.

15. The process according to claim 12, wherein the welding material is made of tin-lead, gold or lead-free metal.

16. The process according to claim 12, wherein the welding material is made of solder paste.

17. The process according to claim 12, wherein the welding material is formed in the opening of the patterned photoresist without extending over the opening of the photoresist.

18. The process according to claim 12, wherein the welding material fills the opening of the patterned photoresist with extending over the opening of the patterned photoresist.

19. The process according to claim 12, wherein the wafer furtrer a back side corresponding to the active side and the rectification operation is grinding the back side of the wafer.

20. The process according to claim 12, wherein the welding material is formed in the openings by a printing process.

21. The process according to claim 12, wherein the welding material is formed in the openings by a electroplating process.
